(19) United States
(12) Patent Application Publication
(10) Pub. No.: US 2022/0100150 A1
(43) Pub. Date: Mar. 31, 2022

(54) MAGNETOMETER BASED ON ATOMIC TRANSITIONS INSENSITIVE TO MAGNETIC FIELD STRENGTH

(71) Applicant: YEDA RESEARCH AND DEVELOPMENT CO. LTD., Rehovot (IL)

(72) Inventors: Roee OZERI, Rehovot (IL); Yehonatan DALLAL, Rehovot (IL); Yotam SHAPIRA, Rehovot (IL); Adiel STERN, Rehovot (IL)

(73) Assignee: YEDA RESEARCH AND DEVELOPMENT CO. LTD., Rehovot (IL)

(21) Appl. No.: 17/426,304

(22) PCT Filed: Feb. 5, 2020
(86) PCT No.: PCT/IL2020/050135

§ 371 Date: Jul. 28, 2021

(30) Foreign Application Priority Data
Feb. 5, 2019 (IL) 264678

(51) Int. Cl. G04F 5/14; G01R 33/24

(52) U.S. Cl. CPC G04F 5/14; G01R 33/24

(57) ABSTRACT

An atomic vector magnetometer and magnetometric methods based on atomic clock transitions unaffected by magnetic field strength for increased quantum coherency time, resulting in improved sensitivity over conventional Zeeman-based atomic magnetometry, where coherency is restricted by sensitivity to magnetic fields. Instead of measuring magnetic field strength in the direction of the quantization axis, as in Zeeman magnetometry, magnetic field strength is measured substantially orthogonal to the quantization axis, via determining the angular displacement of the quantization axis by the magnetic signal field, which is detected by changes in atomic state populations as the quantization axis is rotated relative to the excitation polarization. In addition, the present invention measures magnetic fields instantaneously rather than via accumulated phase shift over time, as in Zeeman magnetometry, thereby providing measurement and spectral analysis of time-varying magnetic fields.

### FIELD

The present disclosure relates to the field of magnetometry, and, in particular, to magnetometry based on atomic transitions.

### BACKGROUND

Magnetometry is an important tool in many applications such as material characterization, geological surveys, and biological imaging. Contemporary high-sensitivity magnetometers, demonstrating sensitivities below one

$$\frac{fT}{\sqrt{Hz}} ,$$

typically make use of superconducting quantum interference devices (SQUID) or atomic systems.

Conventional atomic magnetometry makes use of two atomic quantum states, the energy difference of which depends linearly on magnetic field strength due to the Zeeman effect. In that conventional method, a magnetic field is evaluated from measurements of the accumulated dynamic phase between two Zeeman states in a superposition, as compared to a stable local oscillator (such as a driving RF field). Unfortunately, however, Zeeman coherence time is limited by interaction with magnetic fields, and because the smallest measurable magnetic field strength is inversely proportional to the coherence time, the sensitivity of a Zeeman-based atomic magnetometer has a fundamental physical restriction. It would therefore be advantageous and desirable to have an atomic magnetometer with increased coherence time for improved sensitivity. This goal is achieved by embodiments of the present invention.

### SUMMARY

Various embodiments of the present invention provide magnetometry methods and magnetometer devices that employ quantum superpositions of atomic clock states, which are selected to have transition energies that (to first order) do not depend on magnetic field magnitude, in order to optimize the stability of time-keeping. The coherence times of such superpositions are therefore significantly longer than Zeeman coherence times, and therefore offer the prospect of improved sensitivity.

Although atomic clock transitions are highly insensitive to magnetic field strength, they may be used to measure magnetic field orientation, and, as disclosed herein, they may be used to measure magnetic field vector components. That is, embodiments of the present invention provide vector magnetometers and vector magnetometric methods. As is well-known, a vector magnetometer's orientation can be varied, to thereby measure both a field's magnitude and its direction.

In order to measure an unknown magnetic field (herein denoted as a signal field), embodiments of the present invention provide methods and devices which rely on the geometrical dependence of clock state wave functions on the angular orientation of the quantization axis relative to the polarization of the excitation field. Even in the absence of a dynamically evolving phase, geometric orientation alone may be used to evaluate magnetic signal fields. Thus, embodiments of the present invention gain advantage of the significantly-longer coherence times of atomic clock states to attain improved sensitivity over Zeeman-based measurements, while still providing an ability to measure magnetic fields.

In contrast to Zeeman-based measurements, which measure the strength of the magnetic field component along a quantization axis, embodiments of the present provide a means of measuring the strength of the magnetic signal field component that is substantially orthogonal to the quantization axis. This orthogonal signal field component results in an angular displacement of the background magnetic field relative to the excitation polarization, and therefore alters the relative populations of the two superposed quantum states involved in the transition.

According to certain embodiments of the invention, static magnetic signal fields are measured; and according to other embodiments, time-varying magnetic signal fields are measured, in a manner that allows determining the spectral components of the time-varying signal field.

In summary, as with Zeeman-based methods, the smallest measurable magnetic field strength is inversely proportional to the quantum superposition coherence time. However, in contrast to the Zeeman transitions of conventional atomic magnetometers, the clock transitions utilized by embodiments of the present invention are not sensitive to magnetic field strength and consequently exhibit significantly longer coherence times. These extended coherence times result in higher sensitivity for magnetometric devices and methods according to the present invention.

Therefore, according to an embodiment of the present invention, there is provided a magnetometer for measuring the strength of a magnetic signal field component in a first direction, the magnetometer including: (a) an ensemble of atoms, wherein the atoms have an atomic transition between two distinct atomic states of the atoms, wherein the atomic transition has a characteristic atomic frequency, and wherein the atomic transition is substantially unaffected by magnetic field strength; (b) a variable magnet, for establishing an applied magnetic field in the region of the ensemble of atoms, the applied magnetic field having a second direction substantially orthogonal to the first direction of the magnetic signal field; (c) a microwave generator, for generating microwave radiation, having a frequency at the characteristic atomic frequency for exciting the atomic transition in atoms of the ensemble of atoms; (d) a local oscillator at the characteristic atomic frequency, for determining relative phase; (e) at least two antennas substantially orthogonal to one another, for directing microwave radiation from the microwave generator toward the ensemble of atoms, the at least two antennas directing the microwave radiation in a microwave polarization having an axis in the second direction of the applied magnetic field; and (f) a state population discriminator, for measuring a state population parameter associated with at least one of the distinct atomic states; (g) wherein the magnetometer measures the strength of the magnetic signal field component according to the applied magnetic field, the microwave polarization, and the state population parameter.

In addition, there is also provided by an embodiment of the present invention a method for measuring a magnetic signal field having a first vector direction, the method including: (a) providing a gas of atoms in the region of the magnetic signal field, wherein the atoms have a state transition between two states at a characteristic frequency, and wherein the state transition is substantially unaffected by magnetic field magnitude; (b) providing a variably-settable applied magnetic field having a second vector direction, wherein the second vector direction is substantially orthogonal to the first vector direction of the magnetic signal field; (c) setting the variably-settable applied magnetic field to an initial value much greater than that of the magnetic signal field, such that the magnetic signal field is negligible in comparison therewith; (d) providing a first microwave pulse into the gas of atoms at the characteristic frequency, the first microwave pulse having a

$$\frac{π}{2}$$

duration; (e) reducing the variably-settable applied magnetic field to a final value such that the magnetic signal field is not negligible in comparison therewith; (f) providing a second microwave pulse into the gas of atoms at the characteristic frequency, the second microwave pulse having a

$$\frac{π}{2}$$

duration, wherein the second microwave pulse has a phase θ with respect to the first microwave pulse; (g) measuring a change in a state population of the gas of atoms, wherein the change in the state population is measured from an equal population for each state of the state transition; (h) determining a final phase θ_{f} which maximizes the change in state population of the gas of atoms; and (i) computing a value of the magnetic signal field according to the final value of the variably-settable field and the final phase θ_{f}.

Furthermore, there is also provided by an embodiment of the present invention a method for measuring a magnetic signal field having a first vector direction, the method including: (a) providing a gas of atoms in the region of the magnetic signal field, wherein the atoms have a state transition between two states at a characteristic frequency, and wherein the state transition is substantially unaffected by magnetic field magnitude; (b) providing a variably-settable applied magnetic field having a second vector direction, wherein the second vector direction is substantially orthogonal to the first vector direction of the magnetic signal field; (c) setting the variably-settable applied magnetic field to an initial value much greater than that of the magnetic signal field, such that the magnetic signal field is negligible in comparison therewith; (d) providing a first microwave pulse into the gas of atoms at the characteristic frequency, the first microwave pulse having a

$$\frac{π}{2}$$

duration; (e) reducing the variably-settable applied magnetic field to a final value such that the magnetic signal field is not negligible in comparison therewith; (f) providing a second microwave pulse into the gas of atoms at the characteristic frequency, the second microwave pulse having a

$$\frac{π}{2}$$

duration, wherein the second microwave pulse has a phase

$$\frac{π}{2}$$

with respect to the first microwave pulse; (g) measuring a state population of the gas of atoms; and (h) computing a value of the magnetic signal field according to the final value of the variably-settable field and the state population.

And moreover, there is also provided by an embodiment of the present invention a method for measuring a time-varying magnetic signal field having a first vector direction, the method including: (a) providing a gas of atoms in the region of the magnetic signal field, wherein the atoms have a state transition between two states at a characteristic frequency, and wherein the state transition is substantially unaffected by magnetic field magnitude; (b) providing a variably-settable applied magnetic field having a second vector direction, wherein the second vector direction is substantially orthogonal to the first vector direction of the magnetic signal field; (c) setting the variably-settable applied magnetic field to an initial value much greater than that of the magnetic signal field, such that the magnetic signal field is negligible in comparison therewith; (d) providing a microwave pulse into the gas of atoms at the characteristic frequency, the microwave pulse having a

$$\frac{π}{2}$$

duration; (e) reducing the variably-settable applied magnetic field to a final value such that the magnetic signal field is not negligible in comparison therewith; (f) providing a continuous microwave into the gas of atoms, wherein the continuous microwave has an amplitude modulated in time at a frequency ωₘ; (g) measuring a magnitude of a state population modulated at the frequency ωₘ; and (h) computing a spectral component of the time-varying magnetic signal field at the frequency ωₘ.

### BRIEF DESCRIPTION OF THE DRAWINGS

The subject matter disclosed may best be understood by reference to the following detailed description when read with the accompanying drawings in which:

FIG. 1 schematically illustrates the configuration of a magnetometer device according to an embodiment of the present invention.

FIG. 2 schematically illustrates a microwave-frequency antenna array having two orthogonal antennas for adjusting the polarization of an oscillating electromagnetic field according to an embodiment of the present invention.

FIG. 3 schematically illustrates a population discriminator having a laser and a photodiode according to an embodiment of the present invention.

FIG. 4 is a flowchart of a scanning magnetometric method according to an embodiment of the present invention.

FIG. 5 is a flowchart of another magnetometric method according to a further embodiment of the present invention.

For simplicity and clarity of illustration, elements shown in the figures are not necessarily drawn to scale, and the dimensions of some elements may be exaggerated relative to other elements. In addition, reference numerals may be repeated among the figures to indicate corresponding or analogous elements.

### DETAILED DESCRIPTION

According to various embodiments of the present invention, magnetic signal fields are measured using a quantum superposition of atomic clock states. As noted previously, atomic clock states are selected so that (to first order) their transition frequency is unaffected by magnetic field magnitude. Nevertheless, the relevant wave functions depend on the angular orientation of the quantization axis relative to the polarization of the radio-frequency waves which excite the state transitions.

The expressions |C₁ [symbol] , |C₂ [symbol] , etc., herein denote distinct atomic clock states having an allowed state transition characterized by a precise frequency (or, equivalently, a period). A non-limiting example of a transition between such states is the hyperfine level transition of the ¹³³Cs ground state

$$\vert {6}^{2} {S}_{\frac{1}{2}} , F = 4 , {m}_{F} = 0 〉 ↔ \vert {6}^{2} {S}_{\frac{1}{2}} , F = 3 , {m}_{F} = 0 〉 .$$

The SI definition of the second is based on 9,192,631,770 periods of this transition for a resting ¹³³Cs atom at 0 K.

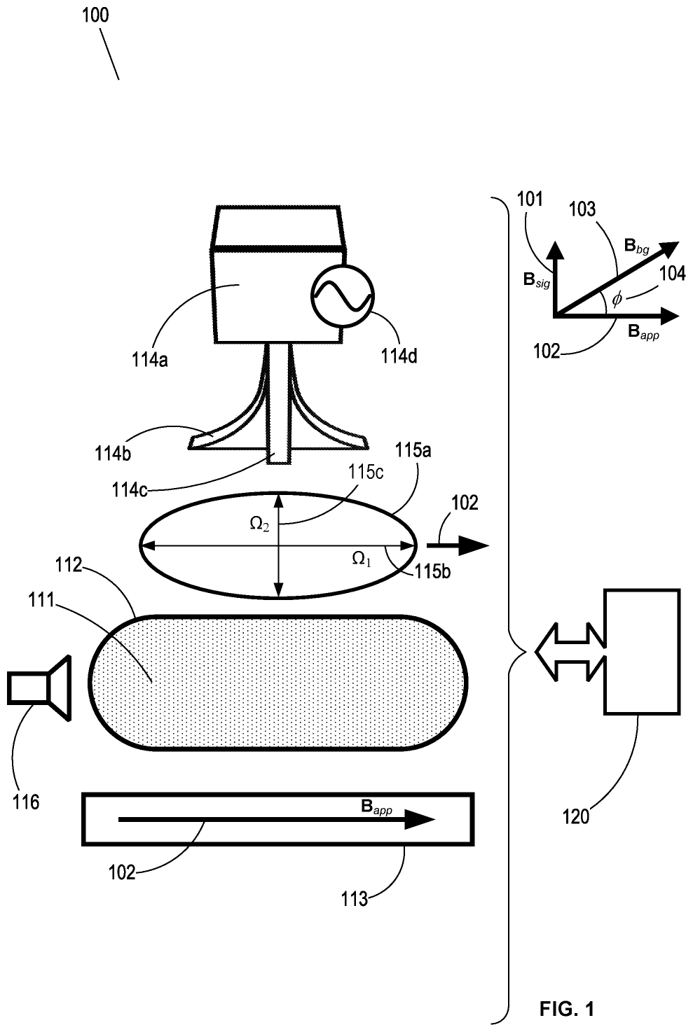

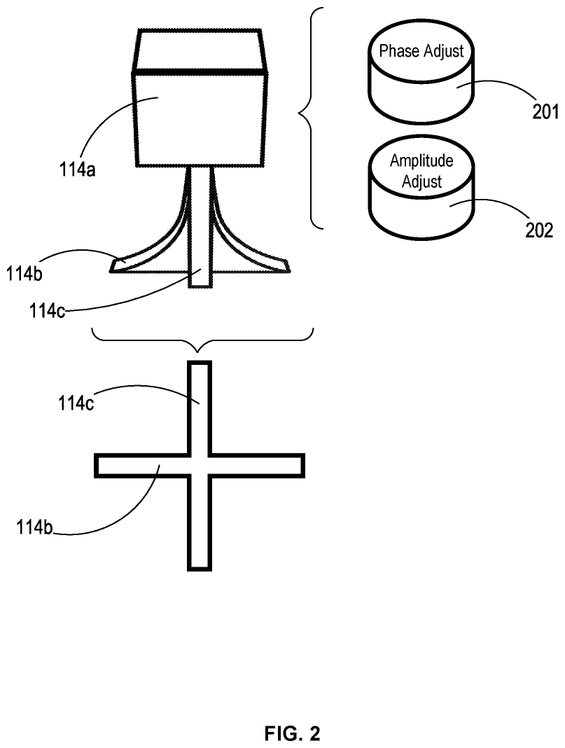

Referring to the schematic illustration of FIG. 1, a magnetometer 100 according to an embodiment of the present invention contains an ensemble of atoms, which in this embodiment is a gas of atoms 111 inside an envelope 112. The atoms of gas 111 are of the sort used in atomic clocks, non-limiting examples of which include alkali metal atoms, such as cesium (e.g., ¹³³Cs) or rubidium (e.g., ⁸⁷Rb), where the atoms have a state transition at a characteristic frequency. A variable magnet 113 establishes a variably-settable applied magnetic field Bₐₚₚ in a direction 102, throughout the region of atom gas 111. A microwave-frequency generator 114a emits microwave radiation at the atomic state transition frequency via antennas 114b and 114c, which are orthogonal to one another so that the polarization of the emitted microwave radiation may be set as desired by individually controlling the amplitudes and phases of the respective antennas (shown in another view in FIG. 2). A stable local oscillator 114d operates at the microwave frequency (the frequency of the atomic transition) and provides the ability to determine relative phases of microwave pulses, as described herein.

The result of the above-described microwave generation, in general, is illustrated conceptually as an elliptically-polarized microwave output 115a having a major axis Ω₁ 115b and a minor axis Ω₂ 115c, which have a ratio denoted herein as

$$\tilde{Ω} = \frac{{Ω}_{2}}{{Ω}_{1}} . \qquad ( Eqn . 1 )$$

Associated with microwave generator 114a is a local oscillator 114c, which is used for phase reference, as discussed herein below.

When excited by the microwave radiation of generator 114a, some of the atoms of gas 111 undergo allowed transitions as outlined below:

A state population discriminator 116 detects and measures a state population parameter, a non-limiting example of which includes measuring the relative populations of the two atomic states |C₁ [symbol] , |C₂ [symbol] . The term state population herein denotes any measure of one or more populations of atoms in a given state or states, including relative measurements expressed as fractions or percentages, and including measurements of a particular state population under one set of conditions relative to measurements of the same particular state population under a different set of conditions.

The above-noted components are managed by a controller 120, which is arranged to perform magnetometric measurements according to various embodiments of the present invention as described herein.

As shown in FIG. 1, major axis Ω₁ 115b is in the same direction 102 as the applied magnetic field Bₐₚₚ of variable magnet 113. Substantially orthogonal to the direction of Bₐₚₚ is a magnetic signal field B_{sig} (the magnetic field to be measured) in a direction 101. Axis 102 may be arbitrarily oriented to be orthogonal to any desired measurement axis 101 by physically orienting device 100.

A net background magnetic field B_{bg} is a vector sum Bₐₚₚ+B_{sig} in a direction 103 which is angularly displaced from direction 102 by an angle ϕ 104. Measurement of angle ϕ 104 according to certain embodiments of the invention is disclosed herein. Once angle ϕ 104 is known, the signal value B_{sig} (the component of B_{sig} orthogonal to Bₐₚₚ, which is ideally the magnitude of B_{sig}) is simply calculated according to the known value of Bₐₚₚ (the magnitude of Bₐₚₚ) as:

B_{sig}=Bₐₚₚ tan ϕ (Eqn. 2)

FIG. 2 also schematically illustrates a phase adjuster 201 and an amplitude adjuster 202 in microwave generator 114a, which has at least one such phase adjuster and at least one such amplitude adjuster, for adjusting the relative phases and amplitudes for the two orthogonal microwave antennas.

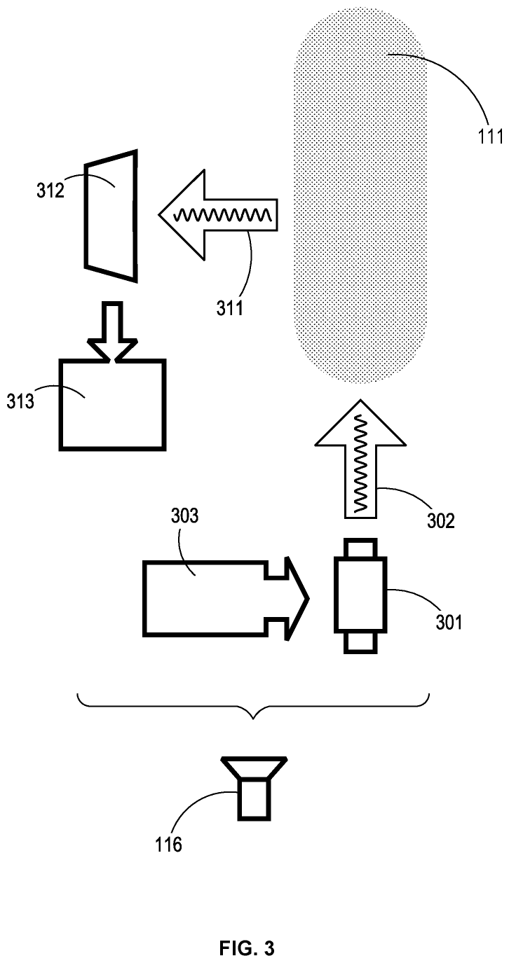

FIG. 3 schematically illustrates details of state population discriminator 116 according to a related embodiment of the invention. In this embodiment, state population discriminator 116 has a laser 301 with a controller 303 for emitting photons 302 that cause atoms of gas 111 having a particular state in gas 111 to fluoresce and emit photons 311 which are detected by a photodetector (such as a photodiode) 312 and input to an analyzer 313 which measures the fluorescence and reports to controller 120 state population data, based on the degree of fluorescence measured. Other embodiments utilize other effects based on atom-photon interactions to measure state populations.

The descriptions below disclose magnetometric methods according to certain embodiments of the present invention which may be performed using a magnetometer device as disclosed above.

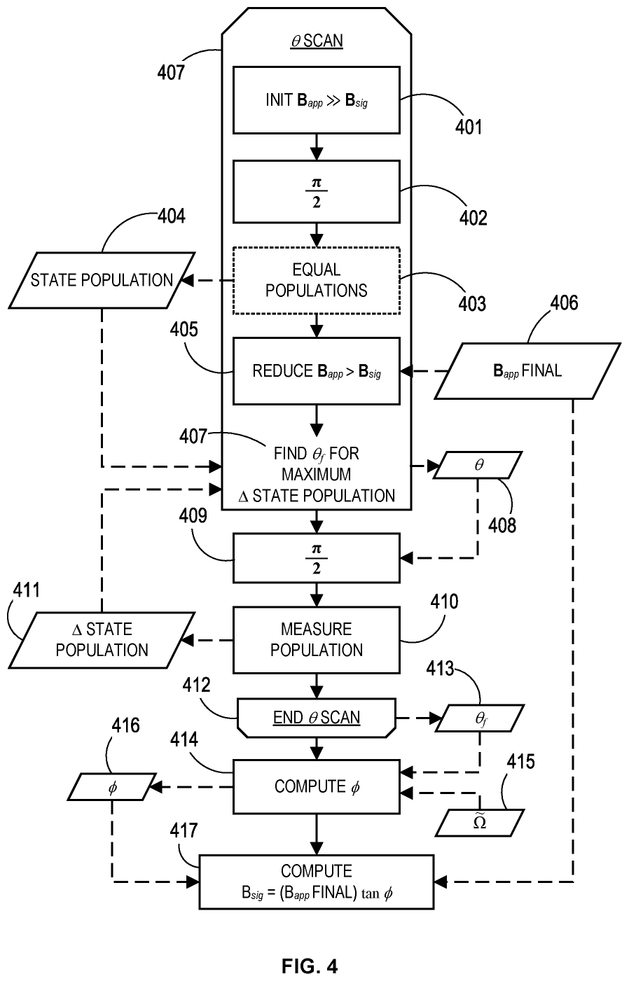

FIG. 4 is a flowchart illustrating a phase-scanning method according to an embodiment of the present invention for measuring the value of the component of the magnetic signal field B_{sig} which is orthogonal to axis 102. In a step 401 the applied magnetic field Bₐₚₚ is initialized to be much greater (e.g., orders of magnitude greater) than the magnetic signal field B_{sig}, so relative to the applied magnetic field, the signal field is negligible and the background magnetic field B_{bg} is essentially the same as Bₐₚₚ, so that B_{sig} has no measurable effect on the atomic transitions. In particular, the polarization of excitation major axis Ω₁ 115 aligns with background magnetic field B_{bg}, so that when, in a step 402, a first

$$\frac{π}{2}$$

elliptically-polarized microwave pulse is applied to the atoms, this results in equal populations of the two atomic states |C₁ [symbol] and |C₂ [symbol] . Here, a

$$“ \frac{π}{2} ”$$

pulse refers to the duration or a pulse rather than its phase. That is, a

$$\frac{π}{2}$$

duration pulse has a time duration tₚ such that

$${Ω}_{1} {t}_{p} = \frac{π}{2} ,$$

where Ω₁ (the major polarization axis) is expressed as an angular frequency. The particular phase of the first

$$\frac{π}{2}$$

pulse in step 402 is arbitrary, but will be taken into account later in the method when applying a second pulse.

At a point 403 after sending in the first pulse at step 402, the atomic state populations 404 are initially equal. In related embodiments, atomic state population measurements are made on only one of the state populations, such as the case when only one of the atomic states has a suitable fluorescence response.

At this point, if another

$$\frac{π}{2}$$

microwave pulse were to be applied to the atoms, there would be no change in initial atomic state population 404. However, in a step 405, the applied magnetic field Bₐₚₚ is reduced so that B_{sig} is no longer negligible in comparison with Bₐₚₚ but such that Bₐₚₚ is still larger than magnetic signal field B_{sig} by at least an order of magnitude (this is important for remaining in the linear regime). The reduced value is stored as a “final” Bₐₚₚ value 406. Now magnetic signal B_{sig} becomes significant, and as illustrated in FIG. 1 background magnetic field B_{bg} no longer aligns with the polarization of excitation major axis Ω₁ 115, but rather is angularly-displaced therefrom by an angle ϕ 104. This affects the wave functions of the atomic state transition |C₁ [symbol] ↔|C₂ [symbol] and results in an altered population measurement, which is herein denoted as a Δ state population, representing the amount of change from the initially-equal populations for the two atomic states in the gas of atoms.

In this embodiment, a phase scan 407 varies a phase θ 408 of a second

$$\frac{π}{2}$$

microwave pulse 409 relative to first

$$\frac{π}{2}$$

microwave pulse 402. The θ phase difference is determined according to local oscillator 114d (FIG. 1). The purpose of the scan is to find a final phase θ_{f} 413 that maximizes a measured Δ state population 411, which is detected by a population measurement 410 during the θ scan. When the θ scan is complete and ends at point 412, final phase θ_{f} 413 and the ratio \tilde{Ω} (from Eqn. 1) are used in a step 414 to compute angle ϕ 416 as a function of θ_{f} and \tilde{Ω} according to the following:

$$sgn ( ϕ ) arccos ( \frac{cos ( ϕ )}{\sqrt{{cos}^{2} ( ϕ ) + {\tilde{Ω}}^{2} {sin}^{2} ( ϕ )}} ) = π - {θ}_{f} \qquad ( Eqn . 3 )$$

In the case of \tilde{Ω}=1 (i.e., the microwave polarization is circular rather than elliptical) Eqn. 3 is easily solved for ϕ:

ϕ=π−θ_{f} (Eqn. 4)

However, in practice. other values of \tilde{Ω} are used (as \tilde{Ω} increases, sensitivity increases and range decreases). In general, Eqn. 3 is solved for ϕ using numerical methods. In a related embodiment of the present invention, a fixed value of \tilde{Ω} is employed, for which case Eqn. 3 is solved numerically to provide a stored data lookup table for controller 120 (FIG. 1) to rapidly convert values of θ_{f} to the corresponding values of ϕ.

In any case, once angle ϕ is obtained, a step 417 immediately provides the measured magnetic signal field value B_{sig} via Eqn. 2.

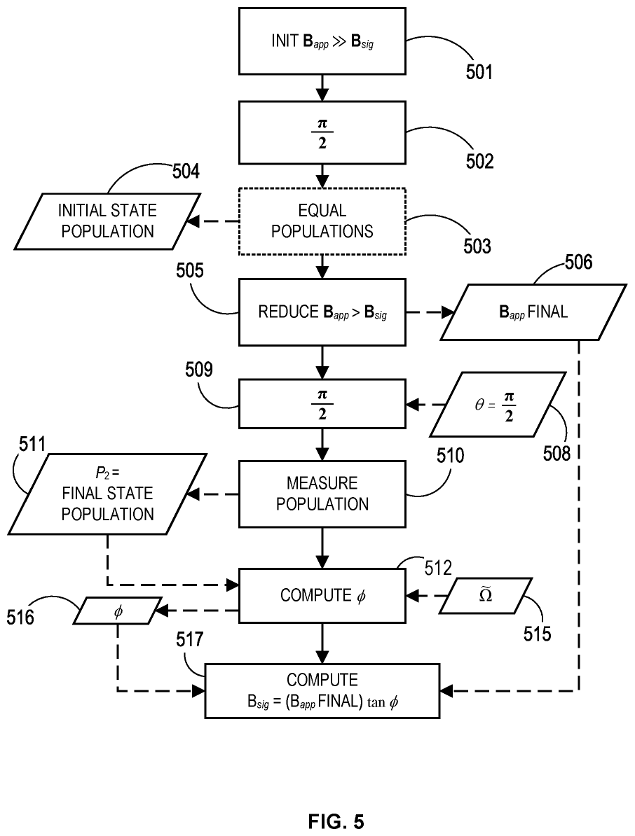

FIG. 5 is a flowchart of another magnetometric method according to a further embodiment of the present invention. The basic principles of this method are similar to those of the method illustrated in FIG. 4, but the measurement sequence of angle ϕ is done in a single step rather than in a scan. Instead of determining a phase shift θ_{f} that maximizes the A state population, a fixed phase shift θ is applied and angle ϕ is determined from a measurement of the final state population P₂.

In a step 501 the applied magnetic field Bₐₚₚ is initialized to be orders of magnitude greater than the magnetic signal field B_{sig}, so relative to the applied magnetic field, the signal field is negligible and the background magnetic field B_{bg} is essentially the same as Bₐₚₚ, so that B_{sig} has no measurable effect on the atomic transitions. In particular, the polarization of excitation major axis Ω₁ 115 aligns with background magnetic field B_{bg}, so that when, in a step 502, a first

$$\frac{π}{2}$$

elliptically-polarized microwave pulse is applied to the atoms, this results in equal populations of the two atomic states |C₁ [symbol] and |C₂ [symbol] . Once again, a

$$“ \frac{π}{2} ”$$

pulse refers to the duration of a pulse rather than its phase.

At a point 503 after sending in the first pulse at step 502, the atomic state populations 504 are initially equal.

In a step 505, the applied magnetic field Bₐₚₚ is reduced to a “final” Bₐₚₚ value 506 so that B_{sig} is no longer negligible—but such that Bₐₚₚ is still larger than magnetic signal field B_{sig} by at least an order of magnitude. As before, magnetic signal B_{sig} becomes significant, and as illustrated in FIG. 1 background magnetic field B_{bg} no longer aligns with the polarization of excitation major axis Ω₁ 115, but rather is angularly-displaced therefrom by an angle ϕ 104.

As noted above, θ phase difference 508 is fixed at

$$\frac{π}{2}$$

(and as previously discussed, this is a phase difference from the first

$$\frac{π}{2}$$

pulse 502 according to local oscillator 114d). A second

$$\frac{π}{2}$$

pulse is applied in a step 509, after which a population measurement 510 is performed to determine the final population P₂ 511.

In a step 512 angle ϕ 516 is computed according to the measured population P₂ 511 by solving Eqn. 5 for 0 in terms of P₂:

$${P}_{2} = \frac{1}{2} - \frac{sin ( \frac{π}{2} \sqrt{{cos}^{2} ( ϕ ) + {\tilde{Ω}}^{2} {sin}^{2} ( ϕ )} )}{2 \sqrt{1 + \frac{{cot}^{2} ( ϕ )}{{\tilde{Ω}}^{2}}}} \qquad ( Eqn . 5 )$$

The choice of

$$θ = \frac{π}{2}$$

leads to the simplified Eqn. 5, which has no dependence on 0.

Although the fixed method of the embodiment illustrated in FIG. 5 is simpler and faster than the scan method illustrated in FIG. 4, it is sensitive to systemic errors in population measurement, whereas the scan method is free of such error.

For small values of angle ϕ, Eqn. 5 is approximated by the first two terms of its power series expansion, which is linear in ϕ:

$${P}_{2} \approx \frac{1}{2} - \frac{\tilde{Ω} ϕ}{2} \qquad ( Eqn . 6 )$$

For \tilde{Ω}ϕ flip values of 0.2, 0.4. and 0.6 the approximations in Eqn. 6 are within about 0.25%, 4%, and 17%, respectively, of the exact P₂ values in Eqn. 5. Thus, in the linear regime where Bₐₚₚ>>B_{sig},

$$ϕ \approx \frac{1 - 2 {P}_{2}}{\tilde{Ω}} \qquad ( Eqn .7 )$$

and thus in the linear regime where Bₐₚₚ>>B_{sig},

$${B}_{sig} \approx \frac{1 - 2 {P}_{2}}{\tilde{Ω}} {B}_{app} \qquad ( Eqn . 8 )$$

### EXAMPLE

A non-limiting practical example of a magnetometer according to an embodiment of the present invention utilizes a clock transition between two hyperfine states of the 5S_{1/2} ground level of ⁸⁷Rb. For this case in a zero magnetic field, |F=1, m_{F}=0 [symbol] (abbreviated as |1,0 [symbol] ) and |F=2, m_{F}=0 [symbol] (abbreviated as |2,0 [symbol] ) are clock states, with their transition energy being unaffected by (insensitive to) the magnetic field to first order.

In this embodiment, a cloud of ultra-cold ⁸⁷Rb atoms is collected from a magneto-optical trap and then evaporatively cooled to about 30 μK in a CO₂ laser quasi-electrostatic trap.

The transition |1,0 [symbol] →|2,0 [symbol] has a resonant frequency of 6.8 GHz, and microwave generator 114a is tuned to this frequency. The atoms are prepared in the |1,0 [symbol] state using optical-pumping pulses on the |F=1 [symbol] →|F=2′ [symbol] D₂ transition combined with microwave pulses. The |2,0 [symbol] state is chosen as the initial state in a |2,0 [symbol] ↔|1,0 [symbol] transition, and a value of \tilde{Ω} is approximately 0.27.

### AC Magnetometry

An embodiment of the present invention offers an additional advantage over conventional Zeeman atomic magnetometry. Zeeman methods measure a dynamic phase which accumulates over the time interval between two

$$\frac{π}{2}$$

pulses. In contrast, this embodiment of the present invention samples the instantaneous magnetic field at the second of the two pulses.

This embodiment generalizes the previously-described magnetometry method to measure time-varying (AC) signals, by replacing the second

$$\frac{π}{2}$$

pulse with a continuous wave whose amplitude is modulated in time to be Ω(t)=Ω₀ cos(ωₘt). Then measuring the magnitude of the resulting state population (modulated at frequency ωₘ) results in a state population coefficient which can be used to determine the spectral component of the magnetic field at the frequency ωₘ. This extends the magnetic field measurement from an instantaneous single-point sampling to a continuous overlap with the modulating signal, effectively creating a spectral filter centered at frequency ωₘ.

1. A magnetometer for measuring the strength of a magnetic signal field component in a first direction, the magnetometer comprising:
an ensemble of atoms, wherein the atoms undergo, an atomic transition between two distinct atomic states at a characteristic atomic frequency, and wherein the atomic frequency of the atomic transition is substantially unaffected by the strength of a magnetic field applied to the ensemble;
a variable magnet, for establishing an applied magnetic field in the region of the ensemble of atoms, the applied magnetic field having a second direction substantially, orthogonal to the first direction of the magnetic signal field;
a microwave generator, for generating microwave radiation, having a frequency at the characteristic atomic frequency for exciting the atomic transition in atoms of the ensemble of atoms;
at least two antennas substantially orthogonal to one another, for directing microwave radiation from the microwave generator toward the ensemble of atoms, the at least two antennas directing the microwave radiation in a microwave polarization having an axis aligned with the applied magnetic field; and
a local oscillator at the characteristic atomic frequency, for determining relative phase between microwave radiation emitted by the antennas;
a state population discriminator, for measuring a state population parameter associated with at least one of the distinct atomic states;
wherein the magnetometer measures the strength of the magnetic signal field component according to the applied magnetic field, the microwave polarization, and the state population parameter.

2. The magnetometer of claim 1, wherein the ensemble of atoms is a gas of atoms, and wherein the magnetometer further comprises an envelope for containing the gas of atoms.

3. The magnetometer of claim 1, wherein the atoms are of an alkali metal.

4. The magnetometer of claim 3, wherein the atoms are selected from a group consisting of cesium atoms and rubidium atoms.

5. The magnetometer of claim 1, wherein the allowed atomic transition is an atomic clock transition.

6. The magnetometer of claim 1, further comprising at least one microwave phase adjuster and at least one microwave amplitude adjuster, for adjusting the microwave polarization.

7. The magnetometer of claim 1, wherein the population discriminator comprises a laser and a photodetector.

8. A method for measuring a magnetic signal field having a first vector direction, the method comprising:
providing a gas of atoms in the region of the magnetic signal field, wherein the atoms undergo a state transition between two states at a characteristic atomic frequency, and wherein the atomic frequency of the state transition is substantially unaffected by the magnitude of a magnetic field applied to the gas of atoms;
providing a variably-settable applied magnetic field having a second vector direction, wherein the second vector direction is substantially orthogonal to the first vector direction of the magnetic signal field;
setting the variably-settable applied magnetic field to an initial value much greater than that of the magnetic signal field, such that the magnetic signal field is negligible in comparison therewith;
providing a first microwave pulse into the gas of atoms at the characteristic frequency, the first microwave pulse having a
$$\frac{π}{2}$$
duration;
reducing the variably-settable applied magnetic field to a final value such that the magnetic signal field is not negligible in comparison therewith;
providing a second microwave pulse into the gas of atoms at the characteristic frequency, the second microwave pulse having a
$$\frac{π}{2}$$
duration, wherein me second microwave pulse has a phase θ with respect to the first microwave pulse;
measuring a change in a state population of the gas of atoms, wherein the change in the state population is measured from an equal population for each state of the state transition;
determining a final phase θ_{f} which maximizes the change in state population of the gas of atoms; and
computing a value of the magnetic signal field according to the final value of the variably-settable field and the final phase θ_{f}.

9. The method of claim 8, wherein determining the final phase θ_{f} which maximizes the change in state population of the gas of atoms is performed by a scan of the phase θ.

10. A method for measuring a magnetic signal field having a first vector direction, the method comprising:
providing a gas of atoms in the region of the magnetic signal field, wherein the atoms undergo a state transition between two states at a characteristic frequency, and wherein the frequency of the state transition is substantially unaffected by the magnitude of a magnetic field applied to the gas of atoms;
providing a variably-settable applied magnetic field having a second vector direction, wherein the second vector direction is substantially orthogonal to the first vector direction of the magnetic signal field;
setting the variably-settable applied magnetic field to an initial value much greater than that of the magnetic signal field, such that the magnetic signal field is negligible in comparison therewith;
providing a first microwave pulse into the gas of atoms at the characteristic frequency, the first microwave pulse having a
$$\frac{π}{2}$$
duration;
reducing the variably-settable applied magnetic field to a final value such that the magnetic signal field is not negligible in comparison therewith;
providing a second microwave pulse into the gas of atoms at the characteristic frequency, the second microwave pulse having a
$$\frac{π}{2}$$
duration, wherein the second microwave pulse has a phase
$$\frac{π}{2}$$
with respect to die first microwave pulse;
measuring a state population of the gas of atoms; and
computing a value of the magnetic signal field according to the final value of the variably-lettable field and the state population.

11. A method for measuring a time-varying magnetic signal field having a first vector direction, the method comprising:
providing a gas of atoms in the region of the magnetic signal field, wherein the atoms undergo a state transition between two states at a characteristic atomic frequency, and wherein the atomic frequency of the state transition is substantially unaffected by the magnitude of a magnetic field applied to the gas of atoms;
providing a variably-settable applied magnetic field having a second vector direction, wherein the second vector direction is substantially orthogonal to the first vector direction of the magnetic signal field;
setting the variably-lettable applied magnetic field to an initial value much greater than that of the magnetic signal field, such that the magnetic signal field is negligible in comparison therewith;
providing a microwave pulse into the gas of atoms at the characteristic frequency, the microwave pulse having a
$$\frac{π}{2}$$
duration;
reducing the variably-settable applied magnetic field to a final value such that the magnetic signal field is not negligible in comparison therewith;
providing a continuous microwave into the gas of atoms, wherein the continuous microwave has an amplitude modulated in time at a frequency ωₘ;
measuring a magnitude of a state population modulated at the frequency ωₘ; and
computing a spectral component of the time-varying magnetic signal field at the frequency ωₘ.

12. The magnetometer of claim 1, wherein the at least two antennas direct the microwave radiation in a microwave polarization having a major axis aligned with the applied magnetic field.
